(19) United States
(12) Patent Application Publication
(10) Pub. No.: US 2014/0191754 A1
(43) Pub. Date: Jul. 10, 2014

(54) METHOD FOR DETERMINING THE EFFECT OF A MEDICAL DEVICE ON THE IMAGE DATA OF A MAGNETIC RESONANCE EXAMINATION AND/OR EXAMINATION SUBJECT EXAMINED BY MEANS OF MAGNETIC RESONANCE

(71) Applicants: Martin Ringholz, Erlangen (DE); Joerg Roland, Hemhofen (DE); Eva Rothgang, Nuernberg (DE)

(72) Inventors: Martin Ringholz, Erlangen (DE); Joerg Roland, Hemhofen (DE); Eva Rothgang, Nuernberg (DE)

(21) Appl. No.: 14/151,005

(22) Filed: Jan. 9, 2014

(30) Foreign Application Priority Data
Jan. 9, 2013 (DE) 102013200188.6

(51) Int. Cl. G01R 33/20; G01R 33/28; G01R 33/44

(52) U.S. Cl. CPC G01R 33/20; G01R 33/44; G01R 33/28
USPC 324/315; 324/318

(57) ABSTRACT

In a method and magnetic resonance apparatus for determining at least one datum providing a measure for the effect of at least one medical device that is to be connected to, or is connected to, an examination subject in the scope of a magnetic resonance examination that is to be executed, or has been executed, on the image data that are to be obtained, or have been obtained, in the scope of a magnetic resonance examination that is to be executed, or has been executed, and/or on the examination subject that is to be examined, or has been examined, in the scope of the magnetic resonance examination that is to be executed, or has been executed, the at least one datum is determined by at least one magnetic resonance thermometric measurement.

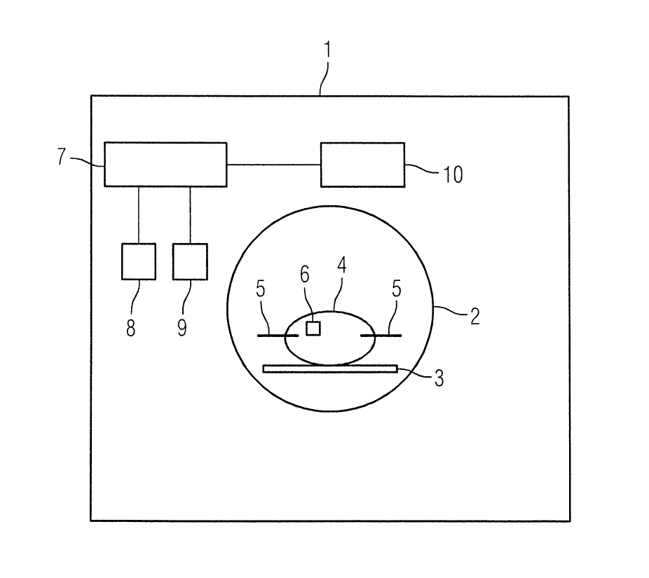

### BACKGROUND OF THE INVENTION

1. Field of the Invention

The present invention relates to a method and a magnetic resonance apparatus for determining at least one datum providing a measure for the effect of that at least one medical device, which is to be connected to, or is connected to, an examination subject in the scope of a magnetic resonance examination that is to be executed, or has been executed, has on the image data that are to be obtained, or have been obtained, in the scope of the magnetic resonance examination that is to be executed, or has been executed, and/or on an examination subject that is to be examined, or has been examined, in the scope of the magnetic resonance examination that is to be executed, or has been executed.

2. Description of the Prior Art

The supporting or immobilizing of certain examination regions of examination subjects, using medical devices, in particular as a component of medical or stereotactic retaining devices, in a stable manner, in particular such that the examination region cannot move during the execution of the magnetic resonance examination in the scope of a magnetic resonance examination that is to be executed, or has been executed, with a magnetic resonance apparatus, is known. In this manner, image artifacts resulting from movements of the examination region, or examination subject, respectively, can be prevented or reduced.

Examples of medical devices of this sort are pin-like elements, frequently referred to as “pins,” that are components of corresponding stereotactic retaining devices, which are firmly attached to the examination subject, i.e. in or adjacent to the examination region, in the scope of the execution of magnetic resonance examinations.

Medical devices of this type, such as the aforementioned pin-like elements, are normally made of materials that are suited for use in the scope of the execution of magnetic resonance examinations. For this purpose, the materials are subjected to numerous requirements. These include requirements pertaining to the mechanical characteristics, the shape, and particularly, to the formation of image artifacts that can be attributed to the medical device, as well as to heating of the examination region of the examination subject that is to be examined, or has been examined, respectively, in the scope of the execution of the magnetic resonance examination, that can be attributed thereto.

Conventionally, these medical devices are normally made out of so-called magnetic resonance compatible materials, such as titanium, ceramics, or composites, or compound materials, such as, e.g. carbon fiber compound materials, or mixtures thereof.

Furthermore, medical devices in the form of implants, which are used, for example, in the field of hip joint or knee joint endoprosthetics, or medical devices for the removal of tissue samples, in particular in the form biopsy needles, are known.

These medical devices are normally, at least in part, made of magnetic or magnetizable metals, such as steel, for example, which make them only suitable to a certain degree, or even entirely unsuitable, for use in the scope of executing magnetic resonance examinations, due to a possibly harmful, material-dependent increase in temperature that can be expected. For this reason, patients with implants of this type are normally barred from magnetic resonance examinations.

It is normal, in the scope of the execution of magnetic resonance examinations, to use temperature measurement probes, by means of which it is possible to perform an in situ temperature measurement, and thus to determine an effect that these medical devices have on the examination region of an examination subject during the execution of the magnetic resonance examination. A problem with the use of these temperature measurement probes is that they normally result in the formation of image artifacts, and thus can have a negative effect on the quality of the image data.

### SUMMARY OF THE INVENTION

The invention thus addresses the fundamental problem of providing a method, that enables a simple determination of the suitability of medical devices that are to be connected to, or are connected to, an examination subject, for the execution of a magnetic resonance examination, in particular with regard to the effect of the medical device on the image data that are to be obtained, or have been obtained, in the scope of a magnetic resonance examination that is to be executed, or has been executed, and/or on the examination subject that is to be examined, or has been examined, in the scope of the magnetic resonance examination that is to be executed, or has been executed.

The problem shall be resolved according to the invention by means of a method of the type specified in the introduction, which is distinguished in that the at least one datum is determined by means of at least one magnetic resonance thermometric measurement.

The present invention is fundamentally based on determining at least one datum, which indicates the effect of a medical device that is to be connected to, or is connected to, an examination subject in the scope of a magnetic resonance examination, on image data that are to be obtained, or have been obtained. The datum can, alternatively or in addition, indicate the effect of the medical device on the examination subject that is to be examined, or has been examined, in the scope of the magnetic resonance examination. For this purpose, according to the invention the at least one datum is determined by at least one magnetic resonance thermometric measurement. The data can also be referred to as effect data.

Magnetic resonance thermometry is a typical measurement method in the field of magnetic resonance examinations, which is well known to those of ordinary skill in that field, so a detailed explanation thereof is not needed herein. Magnetic resonance thermometry is substantially based on determining spatially resolved temperature data for the respective examination region of an examination subject that is to be examined, or has been examined, using various temperature-dependent measurement parameters, such as, e.g., the diffusion coefficient for water, the spin-grid relaxation time T₁ or the resonance frequency of protons in the scope of a magnetic resonance examination.

The data determined according to the invention from at least one magnetic resonance thermometric measurement thus serves to determine, or at least evaluate, the suitability of the medical device for use in the scope of magnetic resonance examinations of an examination subject. Based on the data determined according to the invention, the effect of a medical device on the image data that are to be obtained, or have been obtained, in the scope of the magnetic resonance examination, and/or on the examination subject that is to be examined, or has been examined, in the scope of a magnetic resonance examination that is to be executed, or has been executed, is determined.

The invention thus enables a type of material or substance in the medical device to be checked as to whether it is suitable for use in the scope of a magnetic resonance examination with regard to the image data that are to be obtained, or have been obtained, and/or with regard to the examination subject that is to be examined, or has been examined.

The output of the data to a user can be graphically embedded in the image data generated in the scope of the magnetic resonance examination, i.e. the data can be emitted, or displayed, collectively with the image data. Thus, a quicker overview of the effect of a medical device on the image data that is to be obtained, or is obtained, in the scope of the magnetic resonance examination, and/or on the examination subject that is to be examined, or has been examined, in the scope of the magnetic resonance examination, is possible. Alternatively or additionally, it is possible to present the data on a distinct, dedicated, display, separately from the image data generated in the scope of the magnetic resonance examination.

In particular, for the medical devices in question, pin-like elements (“pins”) used as components of stereotactic retaining devices, or implants, e.g., in the field of hip joint or knee joint endoprosthetics can be evaluated as described above. This is, however, but one example.

The medical device can be a device that is to be connected extracorporeally, to an examination subject within the scope of a magnetic resonance examination, as is the case, for example, with a pin-like element forming a component of a stereotactic retaining device, or measurement electrodes that measure electric currents, or it can be connected to an examination subject independently of a magnetic resonant examination, as is the case, for example, with an implant.

The execution of the magnetic resonance examination takes place using typical magnetic resonance apparatuses that are designed, in particular, for executing magnetic resonance thermometric measurements.

The method according to the invention has neither surgical, therapeutic nor diagnostic aspects, but rather, serves solely for providing a simple way of determining the effect of at least one medical device that is to be connected to, or is connected to, an examination subject in the scope of a magnetic resonance examination, on the image data that are to be obtained, or have been obtained, in the scope of the magnetic resonance examination and/or on the examination subject that is to be examined, or has been examined, in the scope of the magnetic resonance examination. In particular, the latter variant has no surgical, therapeutic, or diagnostic aspects.

The at least one datum that provides a measure for the effect of the medical device on the image data that is to be obtained, or is obtained, in the scope of a magnetic resonance examination, can depict or describe the formation of the image artifacts that can be attributed to the medical device. The extent to which the use of a medical device will result in image artifacts having a negative effect on the image quality of the recorded image data can thus be depicted or described based on the data. For example, the data can indicate, in terms of percentages, the degree to which the quality of the image data, starting from a specific reference value relating to the quality of the image data, is reduced through the effect of the medical device.

Alternatively or additionally, the at least one datum that provides a measure for the effect of the medical device on the examination subject that is to be examined, or has been examined, in the scope of the magnetic resonance examination, can depict or describe the temperature in the region of the medical device connected to the examination subject. From this presentation, the effect on the temperature that can be attributed to the medical device with respect to an examination region associated therewith can be determined by the temperature in the region of the medical device being determined by means the magnetic resonance thermometric measurement. As an of example, based on such data it is possible to graphically depict which temperatures result or occur in the examination region surrounding the medical device in the scope of the magnetic resonance examination. For this purpose, regions of different temperatures can be distinguished from one another by colors, in order to be able to quickly recognize which temperature occurs in which region surrounding the medical device.

The aforementioned region of the medical device is that region of the examination subject, or an examination region associated therewith, that borders directly on the medical device. The region of the medical device can, moreover, include all of the regions of the examination subject, or an examination region associated therewith, in which a temperature change can be observed that can be attributed to the medical device in the scope of a magnetic resonance examination.

It is possible to apply suitable correction methods for susceptibility artifacts in the scope of determining the data. This allows the precision of the data depicting or describing the temperature in the region of the medical device connected to the examination subject in the scope of the magnetic resonance examination to be increased. Correction methods of this type are known, for example, from “K. M. Koch, X. Papademetris, D. L. Rothman D L, R. A. de Graaf R A; Rapid calculations of susceptibility-induced magnetostatic field perturbations for in vivo magnetic resonance; Phys Med Biol; 2006; 51:6381-6402” or “R. Salomir, B. Denis de Senneville, C. T. W. Moonen; A Fast Calculation Method for Magnetic Field Inhomogeneity due to an Arbitrary Distribution of Bulk Susceptibility; Concepts in Magnetic Resonance Part B: Magnetic Resonance Engineering; 2003; 19:26-34.”

It is useful to compare the current datum with at least one comparative datum and, if a predetermined discrepancy is found between the current datum and the comparative datum, at least one visual and/or acoustic warning is issued. Of course, the content of the comparative datum is defined in relation to the respective determined datum, such that these can be compared with one another in a meaningful manner.

For example, in the method according to the invention a datum can be determined that provides a measure of the effect of a medical device on the image data that are to be obtained, or have been obtained, in the scope of the magnetic resonance examination, by depicting or describing the formation of image artifacts that can be attributed to the medical device. The comparative datum the represents qualitative or quantitative threshold values for image artifacts. It can thus be determined, based on the comparison of the datum with the comparative datum, whether the effect of the medical device on the image data that are to be obtained, or have been obtained, in the scope of the magnetic resonance examination, is tolerable or not. For this purpose, the application of image evaluation algorithms relating to image artifacts to the image data may be necessary in order to detect image artifacts within the recorded image data.

In the method according to the invention, data providing a measure for the effect of a medical device on the examination subject that is to be examined, or has been examined, in the scope of the magnetic resonance examination, can be obtained, which depicts or describes the temperature in the region of the medical device connected to the examination subject. The comparative data then contains qualitative or quantitative threshold values for temperatures, including temperature threshold value ranges, which concern temperatures that are not to be exceeded in the region of the medical device. As an example, a temperature threshold value can be established at 42° C., in order to ensure that temperature changes that can be attributed to the medical device do not exceed an absolute temperature for the examination subject, or the examination region, of 42° C.

As noted, if the comparison, in view of threshold values, of the at least one datum with the comparative data results in a discrepancy between the data and the comparative data, at least one visual and/or acoustic warning is issued by means a suitable output unit, such as a display and/or speaker. This allows a user to take suitable measures in the scope of a magnetic resonance examination to prevent temperature-related damage to the examination subject.

In this context, it is also possible that the magnetic resonance examination is automatically aborted, in order to prevent damage to the examination subject or the examination region.

Preferably, the data acquired in the scope of the method according to the invention are stored in a memory. This provides a possibility for recording the data. Furthermore, this makes it possible to retrieve this data in the scope of future magnetic resonance examinations, such that, in the case of a previously evaluated medical device, it is already possible to determine, based solely on the data stored in the memory, what effect the use of that specific medical device will have on the image data that are to be obtained in the scope of the magnetic resonance examination that is to be executed in the future, and/or on the examination subject that is to be examined in the scope of the magnetic resonance examination that is to be executed in the future.

Insofar as a medical device is to be used in the scope of the future execution of a magnetic resonance examination, which is made from a material corresponding to a medical device that has been already used in the scope of a magnetic resonance examination that has been executed, it can be determined, simply and quickly what, if any, effect the medical device that is to be used in the scope of the magnetic resonance examination that is to be executed in the future will have on the image data that are to be obtained in the scope of the magnetic resonance examination that is to be executed. The same applies for the effect of the medical device on the examination subject that is to be examined in the scope of the magnetic resonance examination that is to be executed in the future.

In a further embodiment of the invention, the data can be determined during a magnetic resonance examination, or prior to a magnetic resonance examination. Together therewith, it is possible to use the method according to the invention as a real-time monitoring in the scope of the execution of a magnetic resonance examination. Simultaneously with the recording of image data, it is possible to check whether and to what extent negative effects, which can be attributed to a medical device, occur to the image data obtained in the scope of the magnetic resonance examination, which reduce the quality of the recorded image data.

Alternatively or in addition, it is possible to check whether, and to what extent, effects that can be attributed to a medical device occur to the examination subject examined in the scope of the magnetic resonance examination. In particular, it may be possible to proceed without conventional means for monitoring the examination subject with regard to temperature changes that can be attributed to medical devices in the scope of a magnetic resonance examination of an examination subject.

Likewise, the data can be determined prior to a magnetic resonance examination that is to be executed on an examination subject. As an example, the medical device can be connected to a test object, such as, e.g. a test phantom, in particular, reproduced in the form and volume, and if applicable, tissue of the examination subject that is to be examined, and a magnetic resonance examination can be executed on the test object that is connected to the medical device. This variation may be useful, in particular, for the approval of medical devices that are to be used in the scope of magnetic resonance examinations. As a result, i.e. through the use of a test object, image artifacts that can be attributed to the movement of an examination subject, can be prevented, and thus the precision, or validity of the data can be improved.

The invention also relates to a device for executing a magnetic resonance thermometric measurement, which is designed for executing the method as described above. The device is designed in particular as a magnetic resonance apparatus. The device is advantageously designed such that it is possible to run, in parallel or simultaneously, a magnetic resonance examination, which delivers image data and a magnetic resonance thermometric measurement.

All explanations regarding the method according to the invention apply analogously to the device according to the invention.

### BRIEF DESCRIPTION OF THE DRAWINGS

The single FIGURE is a schematic illustration of a magnetic resonance apparatus for executing the method according to the invention.

### DESCRIPTION OF THE PREFERRED EMBODIMENTS

The single FIGURE is a schematic illustration of a magnetic resonance apparatus 1 for executing the method according to the invention. Within a receiving region 2 of the magnetic resonance apparatus 1, an examination subject 4, such as, e.g. a patient, is located, lying on a support means 3. The examination subject 4, and an examination region thereof is to be examined, such as the head, is supported, or immobilized in a stable position by pin-like elements made of steel, so-called pins, functioning as components of a stereotactic retaining device (not shown). The examination subject 4, or at least the examination region thereof, is thus unable to move, such that image artifacts that can be attributed to movements of the examination subject 4 are prevented. The pin-like elements 5 are to be regarded as medical devices.

The examination subject 4, moreover (as indicated with the numeral 6) can exhibit an artificial hip or knee implant, made at least in part, of steel, which hip or knee implant, which likewise is to be regarded as a medical device.

In the scope of the method according to the invention, at least one datum (and comparative data) is determined, providing a measure for the effect of a medical device, i.e. the pin-like elements 5 and/or the hip or knee implant 6, which is accordingly connected to the examination subject 4, on the image data that are to be obtained, or have been obtained, in the scope of the magnetic resonance examination. Alternatively, or additionally, the datum can indicate the effect of a medical device of this sort to the examination subject 4 that is to be examined, or has been examined, in the scope of the magnetic resonance examination. The datum is obtained, thereby, by means of at least one magnetic resonance thermometric measurement, via the magnetic resonance apparatus 1.

The data can be obtained during (simultaneously with) the execution of the magnetic resonance examination in a continuous manner or in a non-continuous manner at specific points in time, or at defined time intervals, e.g. every five seconds.

The data are determined by a central control device 7 of the magnetic resonance apparatus 1, which has access to suitable computing and program means for determining the data.

It is thus possible for at least one datum to be determined, providing a measure for the effect of the pin-like elements 5 of the hip or knee implant 6 on the image data. The qualitatively or quantitatively data describe the formation of image artifacts that can be attributed to the medical device, or depicts these graphically, for example.

Alternatively, or additionally, at least one datum providing a measure for the effect of the pin-like elements 5, or the hip or knee implants 6, on the examination subject 4 is determined. The qualitatively or quantitatively data describes the temperature in the region of the medical device connected to the examination subject 4, i.e. the pin-like elements 5, or the hip or knee implant 6, or depicts this graphically, for example.

The region of the medical device connected to the examination subject 4 is to be understood as the region of the examination subject 4 directly surrounding the respective medical device. The region of the medical device can furthermore include regions of the examination subject 4 concerning the examination region, in which a temperature change can be recorded that can be attributed to the medical device in the scope of a magnetic resonance examination.

The data determined by the control device 7 can be compared with at least one comparative datum by a comparison device within or connected to the control device 7. If the comparison device, which likewise has access to suitable computing and program means for determining the comparative data, as well as for executing the comparison of the data with the comparative data, indicates a specific, given discrepancy between the data and the comparative data, at least one visual and/or acoustic warning can be issued by means of the control device 7. For this purpose, the control device 7 communicates with displays 8 and loudspeakers 9.

Accordingly, a user can quickly detect whether a medical device, e.g. a hip or knee implant 6, causes a heating of the tissues of the examination subject 4 surrounding said medical device in the scope of the execution of the magnetic resonance examination, which exceeds a tolerable upper temperature limit of, e.g. 42° C. for the tissues of the examination subject 4. Based on the warning, the user can take further suitable measures for preventing temperature-dependent damages to the examination subject 4.

If this is the case, the control device 7 can automatically cause stoppage of the magnetic resonance examination when an upper temperature limit has been exceeded.

The control device 7 also communicates with a data base type memory 10, in which the determined data can be stored. The data stored in the memory 10 can thus always be retrieved, and can, in particular, also be transmitted by means of a data connection, such as, e.g. a data network, to an external memory (not shown) located externally to the magnetic resonance apparatus 1.

In the scope of the method according to the invention, it is likewise possible to determine the data prior to the execution of a magnetic resonance examination of the examination subject 4. In doing so, it is particularly possible to integrate one or more medical devices, such as those that will also be present in the scope of the magnetic resonance examination that is to be executed later, i.e. presently the pin-like elements 5, as well as the hip or knee implant 6, in a test object, in particular a test phantom, that is based on the examination subject 4. In this manner, the effect of the medical device on the image data that are to be obtained, and/or on the examination subject 4 that is to be examined, can already be determined, based on the determined data, before the actual magnetic resonance examination of the examination subject 4.

Based on this pre-examination conducted on a test object, it is possible to assess whether or not a magnetic resonance examination of the examination subject 4 that is to be examined is even possible with the given medical device, i.e. in particular with the image data that is to be recorded being of sufficient quality, or without damage to the examination subject 4.

Fundamentally, the method according to the invention can also be used for testing materials for the creation of medical devices therefrom. This is because it is possible to assess, based on the determined data, whether a specific medical device, or the material used for creating this device, respectively, is at all suited for use in the scope of the execution of magnetic resonance examinations, i.e. that it causes neither significant image artifacts, nor a significant heating of the tissues of an examination subject 4 surrounding this medical device.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for determining at least one datum indicating an effect that at least one medical device has on magnetic resonance data, comprising:
operating a magnetic resonance data acquisition unit to acquire magnetic resonance thermometric data at least from a medical device situated in the magnetic resonance data acquisition unit;
providing said magnetic resonance thermometric data to a processor and, in said processor, automatically generating, from said magnetic resonance thermometric data, at least one datum that represents an effect on magnetic resonance image data that said data acquisition unit is configured to acquire from an examination subject to which said medical device is attached; and
emitting an electronic signal from an output of said processor that represents said at least one datum.

2. A method as claimed in claim 1 comprising generating said at least one datum as an indication of a degree to which said medical device produces image artifacts in an image reconstructed from said magnetic resonance image data.

3. A method as claimed in claim 2 comprising comparing said at least one datum to comparison data representing an acceptable degree of image artifacts in said image and, from said processor, initiating emission of a humanly perceptible alarm when a discrepancy exists between said at least one datum and said comparison data.

4. A method as claimed in claim 3 comprising initiating said alarm when said discrepancy exceeds a predetermined threshold.

5. A method as claimed in claim 1 comprising generating said at least one datum as a depiction or description of temperature in a region of said medical device connected to the examination subject.

6. A method as claimed in claim 5 comprising initiating, from said processor, emission of a humanly perceptible alarm when a discrepancy exists between said at least one datum and said comparison data.

7. A method as claimed in claim 6 comprising initiating said alarm when said discrepancy exceeds a predetermined threshold.

8. A method as claimed in claim 1 comprising storing said at least one datum in a memory accessible by said processor.

9. A method as claimed in claim 1 comprising operating said magnetic resonance data acquisition unit to acquire said magnetic resonance image data, and operating said magnetic resonance data acquisition unit to acquire said magnetic resonance thermometric data during acquisition of said magnetic resonance image data.

10. A magnetic resonance apparatus comprising:
a magnetic resonance data acquisition unit;
a control unit configured to operate the magnetic resonance data acquisition unit to acquire magnetic resonance thermometric data at least from a medical device situated in the magnetic resonance data acquisition unit;
a processor provided with said magnetic resonance thermometric data to a processor and, in said processor being configured to automatically generate, from said magnetic resonance thermometric data, at least one datum that represents an effect on magnetic resonance image data that said data acquisition unit is configured to acquire from an examination subject to which said medical device is attached; and
said processor being configured to emit an electronic signal from an output of said processor that represents said at least one datum.
